(19) United States
(12) Patent Application Publication
(10) Pub. No.: US 2018/0129848 A1
(43) Pub. Date: May 10, 2018

(54) CHIP PACKAGING STRUCTURE AND PACKAGING METHOD

(71) Applicant: China Wafer Level CSP Co., Ltd., Suzhou, Jiangsu (CN)

(72) Inventors: Zhiqi Wang, Suzhou, Jiangsu (CN); Ying Yang, Suzhou, Jiangsu (CN); Qiong Yu, Suzhou, Jiangsu (CN); Wei Wang, Suzhou, Jiangsu (CN)

(73) Assignee: China Wafer Level CSP Co., Ltd., Suzhou, Jiangsu (CN)

(21) Appl. No.: 15/573,552

(22) PCT Filed: Sep. 15, 2015
(86) PCT No.: PCT/CN2015/089595

§ 371 Date: Nov. 13, 2017

(30) Foreign Application Priority Data
May 19, 2015 (CN) 201510256201.2

(51) Int. Cl. G06K 9/00; H01L 23/31; H01L 23/29; H01L 21/56

(52) U.S. Cl. CPC G06K 9/0002; H01L 23/31; H01L 23/291; H01L 23/293; H01L 21/56; H01L 2924/1815; H01L 2224/04042; H01L 2224/92247; H01L 2224/73265; H01L 2224/48091; H01L 2224/32225

(57) ABSTRACT

A chip packaging structure and a chip packaging method are provided. The chip packaging structure includes: a substrate; a sensing chip coupled to the substrate, where the sensing chip includes a first surface and a second surface facing away from the first surface, the sensing chip further includes a sensing region located in the first surface, and the second surface of the sensing chip faces to the substrate; and a molding layer located on the substrate and a portion of the first surface of the sensing chip, where the molding layer exposes the sensing region.

### CROSS REFERENCE TO RELATED APPLICATION

The present application claims priority to Chinese Patent Application No. 201510256201.2, titled “PACKAGING STRUCTURE AND PACKAGING METHOD FOR FINGERPRINT RECOGNITION CHIP”, filed with the Chinese State Intellectual Property Office on May 19, 2015, which is incorporated herein by reference in its entirety.

### FIELD

The present disclosure relates to the technical field of semiconductor fabrication, and particularly to a chip packaging structure and a chip packaging method.

### BACKGROUND

With the progress of modern society, people pay more and more attention to personal identifications and personal information security. Due to the uniqueness and invariance of human fingerprints, fingerprint recognition technologies have the features of good security, high reliability and simple use, and thus are widely used in various fields related to personal information security protection. With the continuous development of science and technology, information security of all kinds of electronic products is always one of the key points of the development of technologies. Particularly, information security is more important for mobile terminals, such as cell phones, laptops, tablet computers and digital cameras.

The sensing mode of a fingerprint recognition device includes a capacitive (electric field) sensing mode and an inductive sensing mode. The fingerprint recognition device obtains fingerprint information of a user by extracting a fingerprint of the user and converting the fingerprint of the user into an electrical signal as an output. In particular, FIG. 1 is a schematic cross-sectional view of a fingerprint recognition device, which includes a substrate 100, a fingerprint recognition chip 101 coupled to a surface of the substrate 100 and a glass substrate 102 covering a surface of the fingerprint recognition chip 101.

Taking a capacitive fingerprint recognition chip as an example, the fingerprint recognition chip 101 includes one or more capacitive plates. Since the skin or subcutaneous of a user's finger has raised ridges and recessed valleys, when the user's finger 103 contacts a surface of the glass substrate 102, a distance between the ridge and the fingerprint recognition chip 101 is different from a distance between the valley and the fingerprint recognition chip 101. Therefore, a capacitance value between the ridge of the user's finger 103 and the capacitive plate is different from a capacitance value between the valley of the user's finger and the capacitive plate. The fingerprint recognition chip 101 can acquire the different capacitance values and convert them into corresponding electrical signals for output, and the fingerprint recognition device can acquire the fingerprint information of the user after collecting the received electrical signals.

However, a fingerprint recognition device according to conventional technologies has a high requirement on the sensitivity of the sensing chip. In this case, the fingerprint recognition device is limited in fabrication and application and has a high fabricating cost.

### SUMMARY

A chip packaging structure and a chip packaging method are provided according to embodiments of the present disclosure, with the chip packaging structure achieving improved sensitivity, a simplified package process and a reduced fabricating cost.

A chip packaging method is provided according to an embodiment of the present disclosure. The chip packaging method includes:

providing a substrate;
coupling a sensing chip to the substrate, where the sensing chip includes a first surface and a second surface facing away from the first surface, the sensing chip further includes a sensing region located in the first surface, and the second surface of the sensing chip faces to the substrate; and
forming a molding layer on the substrate and a portion of the first surface of the sensing chip, where the molding layer exposes the sensing region.

Optionally, the sensing chip further includes a peripheral region which is located in the first surface and encloses the sensing region.

Optionally, the peripheral region is covered by the molding layer.

Optionally, the molding layer is formed by an injection molding process.

Optionally, the injection molding process includes: providing a mold, where the mold includes a fourth surface and has a sensing-corresponding region and a peripheral-corresponding region, the fourth surface includes a surface of the peripheral-corresponding region and a surface of the sensing-corresponding region that is higher than the surface of the peripheral-corresponding region; pressing the fourth surface of the mold towards the substrate and the sensing chip to form a molding space between the substrate and the mold, where the sensing-corresponding region of the mold corresponds to the sensing region of the sensing chip; and filling a mold compound into the molding space and curing the mold compound to form the molding layer.

Optionally, a chip circuit is arranged in the sensing region of the sensing chip and peripheral region of the sensing chip, a first pad is arranged on a surface of the peripheral region of the sensing chip and is electrically connected to the chip circuit.

Optionally, the substrate further includes a third surface to which the sensing chip is coupled, and a second pad is arranged on the third surface of the substrate.

Optionally, the method further includes: forming a conductive wire before forming the molding layer, where two ends of the conductive wire are respectively connected to the first pad and the second pad.

Optionally, the molding layer wraps the conductive wire.

Optionally, a distance between a surface of the molding layer and the first surface of the sensing chip ranges from 100 microns to 150 microns, and the molding layer is made of polymer material. A chip packaging structure is further provided according to an embodiment of the present disclosure. The chip packaging structure includes:

a substrate;
a sensing chip coupled to the substrate, where the sensing chip includes a first surface and a second surface facing away from the first surface, the sensing chip further includes a sensing region located in the first surface and the second surface of the sensing chip faces to the substrate; and
a molding layer located on the substrate and a portion of the first surface of the sensing chip, where the molding layer exposes the sensing region. Optionally, the sensing chip further includes a peripheral region which is located in the first surface and encloses the sensing region.

Optionally, the peripheral region is covered by the molding layer.

Optionally, the structure further includes: a chip circuit arranged in the sensing region of the sensing chip and the peripheral region of the sensing chip; and a first pad located on a surface of the peripheral region of the sensing chip; where the chip circuit is electrically connected to the first pad.

Optionally, the structure further includes that: the substrate further includes a third surface to which the sensing chip is coupled, and a second pad is arranged on the third surface of the substrate.

Optionally, the structure further includes: a conductive wire, where two ends of the conductive wire are connected to the first pad and the second pad respectively.

Optionally, the molding layer wraps the conductive wire.

Optionally, a distance between a surface of the molding layer and the first surface of the sensing chip ranges from 100 microns to 150 microns, and the molding layer is made of polymer material

### BRIEF DESCRIPTION OF THE DRAWINGS

FIG. 1 is schematic cross-sectional structural view of a fingerprint recognition device;

FIG. 2 is schematic cross-sectional structural view of a structure for a fingerprint recognition chip; and

FIGS. 3 to 8 are schematic cross-sectional structural views of a fingerprint recognition chip in a forming process according to an embodiment of the present disclosure.

### DETAILED DESCRIPTION OF EMBODIMENTS

As described in the background, the fingerprint recognition device according to the conventional technologies has the high requirement on the sensitivity of the sensing chip. Therefore, the fingerprint recognition device is limited in fabrication and application and has the high fabricating cost.

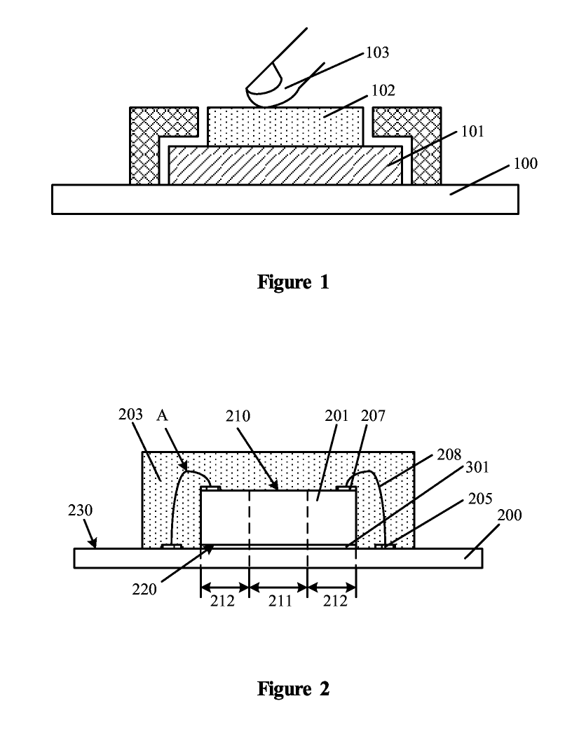

It is found by research that, referring to FIG. 1, a surface of the fingerprint recognition chip 101 is covered with a glass substrate 102 for protecting the fingerprint recognition chip 101, and a user's finger 103 directly contacts with the glass substrate 102. In this case, the glass substrate 102 is thick to ensure adequate protection capability of the glass substrate 102. However, due to the thick glass substrate 102, the fingerprint recognition chip 101 is required to have a high sensitivity to accurately extract a user's fingerprint. However, it is difficult to fabricate the fingerprint recognition chip with the high sensitivity and the fabricating cost is high, thereby limiting the fingerprint recognition chip in application and promotion.

In order to reduce the requirement on the sensitivity of the fingerprint recognition chip, another fingerprint recognition chip structure is provided. Referring to FIG. 2, the fingerprint recognition chip includes a substrate 200, a sensing chip 201, multiple conductive wires 208 and a molding layer 203. The substrate 200 includes a first surface 230 arranged with multiple first pads 205. The sensing chip 201 is arranged towards the first surface 230 of the substrate 200. The sensing chip 201 includes a first surface 210 and a second surface 220 facing away from the first surface 210. The second surface 220 of the sensing chip 201 is arranged on the first surface 210 of the substrate 200. The sensing chip 201 includes a sensing region 211 located on the first surface 210 and a peripheral region 212 that encloses the sensing region 211. The surface of the sensing chip 201 in the peripheral region 212 is arranged with multiple second pads 207, and the second pads 207 correspond to the first pads 205 in positions in a one-to-one manner and have the same quantities as the first pads 205. Two ends of the conductive wire are electrically connected to the first pad 205 and the second pad 207 respectively. A point at the top of the conductive wire 208 having a maximum distance to the first surface 210 of the substrate 200 is determined as a vertex A, and the distance between the vertex A and the first surface 210 of the sensing chip is determined as a first distance. The molding layer 203 is arranged on the surfaces of the sensing chip 201 and the substrate 200 and is made of polymer material. The molding layer 203 wraps the conductive wires 208 and the sensing chip 201. A surface of the molding layer 203 over the sensing region 201 is flat. A distance between the surface of the molding layer 203 and the first surface 210 of the sensing chip 201 is determined as a second distance, which is greater than the first distance.

The molding layer located on the sensing region 211, instead of a traditional glass substrate, is used to directly contact with the user's finger. Since the glass substrate is removed, it is advantageous for improving a sensing capability of the sensing chip 201. However, since the sensing chip 201 is electrically connected to the substrate 200 with the conductive wire 208, and the conductive wire 208 has the vertex A which is higher than the first surface 210 of the sensing chip 201, the second distance between the surface of the molding layer 203 and the first surface 210 of the sensing chip 201 should be greater than the first distance between the vertex A of the conductive wire 208 and the first surface 210 of the sensing chip 201, in order to completely wrap the conductive wire 208 by the molding layer 203. Therefore, the molding layer 203 located on the first surface 210 of the sensing chip 201 is still thick. In addition, since the molding layer 203 further covers the sensing region 211 of the sensing chip 201, the molding layer 203 over the surface of the sensing region 211 is still thick, which is disadvantageous for improving the sensing sensitivity of the sensing chip 201, resulting in a poor sensing capability of the formed packaging structure.

Packaging structure and packaging method for a fingerprint recognition chip are provided according to embodiments of the present disclosure. In the packaging method, after a sensing chip (such as the fingerprint recognition chip) is coupled to a surface of a substrate, a molding layer is formed on a surface of a substrate and a portion of a surface of the sensing chip and exposes a sensing region of the sensing chip. In this case, the molding layer fixes the sensing chip and the substrate with each other, and completely exposes the sensing region of the sensing chip while protecting a region of the sensing chip other than the sensing region. Since the surface of the sensing region is not covered, the sensitivity capability of the sensing chip can be fully utilized. Therefore, the sensitivity of formed packaging structure of the fingerprint recognition chip is improved.

The above objects, technical solutions and advantages of the present disclosure will be better understood from the following detail description of embodiments of the present disclosure made with reference to the drawings.

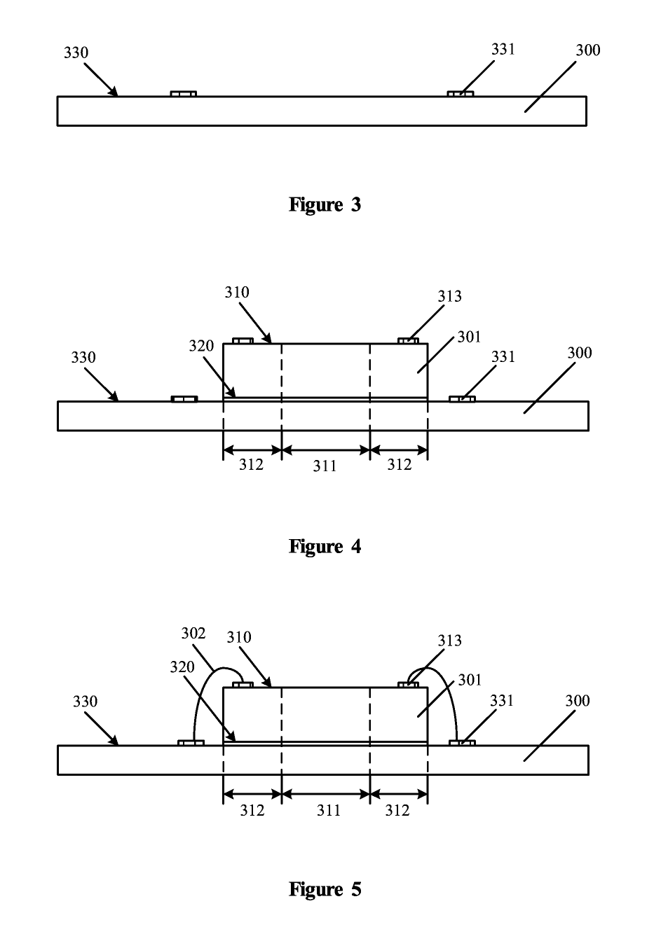

FIGS. 3 to 8 are schematic cross-sectional structural views of a fingerprint recognition chip in a forming process according to an embodiment of the present disclosure.

Reference is made to FIG. 3, in which a substrate 300 is provided.

The substrate 300 may be a rigid substrate or a flexible substrate. In the present embodiment, the substrate 300 is a rigid substrate such as a PCB substrate, a glass substrate, a metal substrate, a semiconductor substrate or a polymer substrate.

In the embodiment, the substrate 300 includes a third surface 330 which is to be coupled to a sensing chip subsequently. The third surface 330 of the substrate 300 includes a wiring layer (not shown) and a second pad 331. The wiring layer is connected to the second pad 331, and the second pad 331 is to be electrically connected to a chip circuit on a surface of the sensing chip.

In an embodiment, a connection portion is formed at one end of the substrate 300, for electrically connecting the sensing chip with an external circuit. The connection portion may be made of conductive material, and is electrically connected to the wiring layer. In this case, the chip circuit on the sensing chip may be electrically connected to an external circuit or external device via the wiring layer and the connection portion on the third surface 330 of the substrate 300, to transfer an electrical signal.

Next, the sensing chip is coupled to the surface of the substrate 300 with steps described hereinafter.

Referring to FIG. 4, the sensing chip 301 is fixed on the surface of the substrate 300. The sensing chip 301 includes a first surface 310 and a second surface 320 facing away from the first surface 310. The sensing chip 301 includes a sensing region 311 located on the first surface 310, and the second surface 320 of the sensing chip 301 faces to the substrate 300.

In the present embodiment, a first adhesive layer is adhered to the second surface 320 of the sensing chip 301 as well as the third surface 330 of the substrate 300, thereby fixing the sensing chip 301 to the third surface 330 of the substrate 300. The sensing chip 301 can be coupled to the substrate 300 by a wire bonding process, that is, the sensing chip 301 is electrically connected to the wiring layer on the surface of the substrate 300.

In another embodiment, a first adhesive layer may be formed on the third surface 330 of the substrate 300, and the sensing chip 301 is adhered to the surface of the first adhesive layer, to fix the sensing chip 301 to the surface of the substrate 300.

In the present embodiment, in the sensing region 311 of the sensing chip 301, a sensing device for acquiring user's fingerprint information is formed. The sensing device includes a capacitive structure or an inductive structure, with which the user's fingerprint information can be detected and received in the sensing region 311.

The first surface 310 further includes a peripheral region 312 which is located on the first surface 310 and encloses the sensing region 311. A chip circuit is further formed in the sensing region 311 and peripheral region 312 of the sensing chip 301 and is electrically connected to the sensing device in the sensing region 311, for processing an electrical signal outputted by the sensing device.

In the embodiment, at least one capacitive plate is formed in the sensing region 311, once a user's finger is placed on the surface of the sensing region 311, a capacitive structure is formed by the capacitive plate and the user's finger. In addition, the sensing region 311 can acquire a difference between a capacitance value of a capacitive structure formed by a ridge the user's finger surface and the capacitive plate and a capacitance value of a capacitive structure formed by a valley of the user's finger surface and the capacitive plate, and the capacitance difference is processed and outputted by the chip circuit, to obtain the user's fingerprint data.

In the embodiment, since the molding layer to be subsequently formed exposes the sensing region 311 of the sensing chip 301, the user's fingerprint can directly contact the surface of the sensing region 311. In this case, in order to ensure that the user's finger is isolated from the capacitive plate in the sensing region 311, the surface of the sensing region 311 of the sensing chip 301 is arranged with a passivation layer made of insulation material. The passivation layer serves as a dielectric layer between the user's finger and the capacitive plate to form the capacitive structure with which the user's fingerprint information can be acquired. In addition, with the passivation layer, not only the chip circuit and the sensing device in the sensing region 311 can be further prevented from abrasion, but also the chip circuit and the sensing device are electrically insulated from the external environment.

The sensing chip 301 further includes a first pad 313 located on a surface of the peripheral region 312 of the sensing chip. The chip circuit is electrically connected to the first pad 313, and the first pad 313 can be electrically connected to the wiring layer on the surface of the substrate 300 by a subsequent wire bonding process.

Reference is made to FIG. 5, in which the sensing chip 301 is coupled to the substrate 300.

Before the molding layer is formed, a conductive wire 302 is formed, and two ends of the conductive wire 302 are respectively connected to the first pad 313 and a second pad 331.

To couple the sensing chip 301 to the substrate 300 is to electrically connect the sensing chip 301 with the substrate 300. In the embodiment, the sensing chip 301 is coupled to the substrate 300 by the wire bonding process.

In the embodiment, before the molding layer is subsequently formed, the conductive wire 302 is formed by the wire bonding process, and two ends of the conductive wire 302 are respectively connected to the first pad 313 and the second pad 331 to electrically connect the sensing chip 301 to the substrate 300. The conductive wire 302 can electrically connect the chip circuit to the wiring layer on the surface of the substrate 300, and the wiring layer is electrically connected to the connection portion. In this way, the chip circuit and the sensing region 311 located on the surface of the sensing chip 301 can transmit the electrical signal with an external circuit or device. The conductive wire 302 is made of metal such as copper, tungsten, aluminum, gold or silver. The wire bonding process adopted for electrically connecting the sensing chip 301 to the substrate 300 is simple, and has a low process cost.

The wire bonding process includes: providing a conductive wire 302, and connecting two ends of the conductive wire 302 respectively to the first pad 313 and the second pad 331 by a welding process. The conductive wire 302 is made of metal such as copper, tungsten, aluminum, gold or silver.

Since the conductive wire 302 is connected between the first pad 313 and the second pad 331, the conductive wire 302 is bent. A point on the conductive wire 302 having a maximum distance to the surface of the substrate 300 is determined as a vertex, and the vertex is higher than the first surface 310 of the sensing chip 301. The conductive wire 302 is to be subsequently wrapped by a molding layer, so that the conductive wire 302 is electrically isolated from the sensing chip 301 as well as from the external environment. Therefore, the vertex should be lower than the surface of the molding layer to be subsequently formed, so that the molding layer to be subsequently formed can completely wrap the conductive wire 302 to prevent the conductive wire 302 from being exposed.

The molding layer is formed on the surface of the substrate 300 and a portion of the surface of the sensing chip 301, and exposes the sensing region 311. The molding layer is formed by an injection molding process, and steps for forming the plastic sealing layer are described hereinafter.

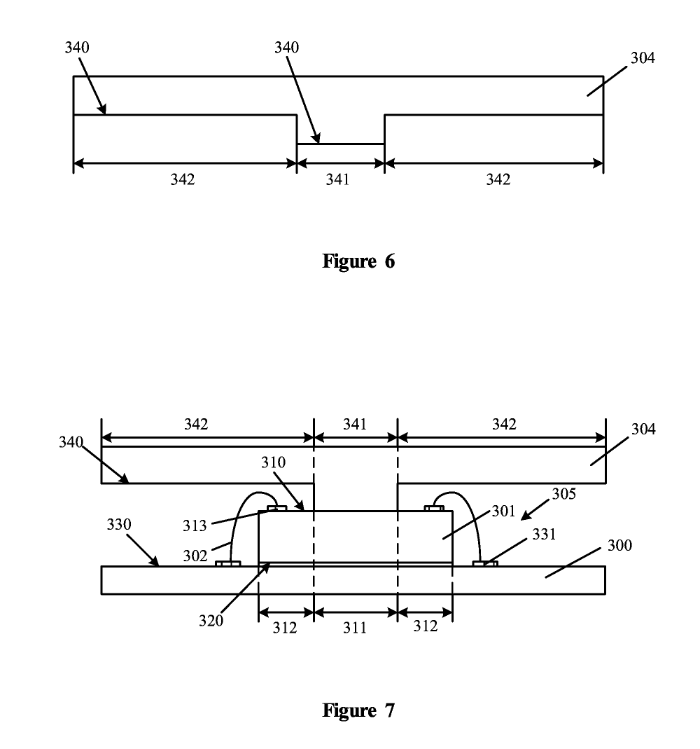

Reference is made to FIG. 6, in which a mold 304 is provided. The mold 304 includes a fourth surface 340, and includes a sensing-corresponding region 341 and a peripheral-corresponding region 342. A surface of the sensing-corresponding region 341 is higher than a surface of the peripheral-corresponding region 342.

The mold 304 is configured to define a shape of the molding layer to be subsequently formed. In the embodiment, the molding layer to be subsequently formed should expose the sensing region 311 of the sensing chip 301, while the peripheral region 312 of the sensing chip 301 and the surface of an exposed region of the substrate 300 need to be covered and protected by the molding layer. In this case, the shape of the mold 304 should correspond to that of the molding layer to be subsequently formed.

The fourth surface 340 of the mold 304 is to be pressed towards the substrate 300 and the sensing chip 301 later, with the sensing-corresponding region 341 of the mold 304 corresponding to the sensing region 311 of the sensing chip 301 and the peripheral-corresponding region 342 of the mold corresponding to the peripheral region 312 of the sensing chip 301 and the surface of the exposed region of the substrate 300. Since the surface of the sensing-corresponding region 341 is higher than the surface of the peripheral-corresponding region 342, by pressing the mold 304 towards the substrate 300 and the sensing chip 301, the surface of the sensing-corresponding region 341 can contact the surface of the sensing region 311 while a molding space is formed between the peripheral-corresponding region 342 and the peripheral region 312 and between the peripheral-corresponding region 342 and the substrate 300. The molding space is for forming the molding layer.

A height difference between the surface of the sensing-corresponding region 341 and the surface of the peripheral-corresponding region 342 is a thickness of the molding layer to be formed on the surface of the peripheral region 312. In the embodiment, the height difference between the surface of the sensing-corresponding region 341 and the surface of the peripheral-corresponding region 342 ranges from 100 microns to 150 microns.

Reference is made to FIG. 7, in which the fourth surface 340 of the mold 304 is pressed towards the substrate 300 and the sensing chip 301, to form a molding space 305 between the substrate 300 and the mold 304. The sensing-corresponding region 341 of the mold 304 corresponds to the sensing region 311 of the sensing chip 301, and the peripheral-corresponding region 342 of the mold 304 corresponds to the peripheral region 312 of the sensing chip 301.

The molding space 305 formed by the mold 304, the sensing chip 301 and the substrate 300 is used for forming a molding layer.

In the embodiment, in the case that the fourth surface 340 of the mold 304 is pressed towards to the substrate 300 and the sensing chip 301, the surface of the sensing-corresponding region 341 contacts the surface of the sensing region 311 of the sensing chip 301. After the molding layer is formed in the molding space 305, the molding layer will not cover the sensing region 311, that is, the formed molding layer exposes the sensing region 311. In this case, the user's finger can directly contact the sensing region 311, thereby improving the sensitivity of the sensing chip 301.

In another embodiment, there is a preset distance between the surface of the sensing-corresponding region 341 and the surface of the sensing chip 301. Since the surface of the sensing-corresponding region 341 protrudes from the surface of the peripheral-corresponding region 342, after the fourth surface 340 of the mold 304 is pressed towards the substrate 300 and the sensing chip 301, a distance between the surface of the peripheral-corresponding region 342 and the peripheral region 312 of the sensing region 301 is greater than the preset distance. That is to say, a portion of the molding layer to be subsequently formed on the peripheral region 312 is thicker than a portion of the molding layer to be subsequently formed on the surface of the sensing region 311. In this case, the surface of the sensing region 311 is protected by the molding layer and the molding layer is thin, having little influence on the sensitivity of the sensing chip 301.

The portion of the fourth surface 340 corresponding to the peripheral-corresponding region 342 is lower than the portion of the fourth surface 340 corresponding to the sensing-corresponding region 341. The molding space can be formed between the portion of the fourth surface 340 corresponding to the peripheral-corresponding region 342 and the peripheral region 312 of the sensing region 301 and between the portion of the fourth surface 340 corresponding to the peripheral-corresponding region 342 and the exposed region of the substrate 300. Therefore, after the molding layer to be subsequently formed in the molding space can cover the surface of the peripheral region 312 of the sensing region 301 and the surface of the substrate 300.

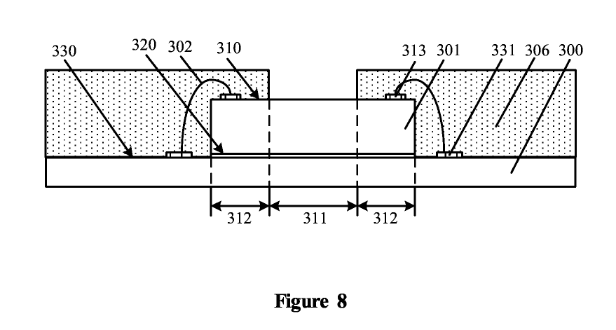

Reference is made to FIG. 8, in which mold compound is filled into the molding space 305 (as shown in FIG. 7) and cured, to form a molding layer 306.

In the embodiment, the molding layer 306 covers the surface of the peripheral region 312 while exposing the surface of the sensing region 311. In this way, the user's finger can directly contact the sensing region 311, thereby improving the sensitivity of the sensing chip. In other embodiments, the surface of the sensing region 311 may be covered by the molding layer which is thinner than the molding layer covering the surface of the peripheral region 312.

The molding layer 306 is made for protecting the peripheral region 312 of the sensing region 301, the conductive wire 302 and the substrate 300, and for fixing the sensing chip 301 to the surface of the substrate 300. In addition, the molding layer 306 further wraps the conductive wire 302, thereby electrically isolating the conductive wire 302 from the sensing chip 301 or the external environment.

The vertex of the conductive wire 302 is higher than the first surface 310 of the sensing chip 301, and the molding layer 306 can completely wrap the conductive wire 304 only if the surface of the molding layer 306 is higher than the vertex of the conductive wire 302. In the embodiment, the distance between the surface of the molding layer 306 and the surface of the peripheral region 312 of the sensing chip 301 ranges from 100 microns to 150 microns.

The molding layer 306 is made of polymeric material which has good flexibility, ductility and covering capability. The polymer material may be epoxy resin, polyimide resin, benzocyclobutene resin, polybenzoxazole resin, polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate copolymer, polyvinyl alcohol or other appropriate polymeric material.

The molding layer 306 is formed by a transfer molding process. Mold compound in fluid form is injected in the molding space 305 to fill up the molding space 305, and then is cured to form the molding layer 306. After the mold compound is cured, the mold 304 is removed (as shown in FIG. 7).

In an embodiment, a protection ring is further formed on the surface of the substrate 300 and encloses the sensing chip 301 and the molding layer 306. The protection ring is made of metal and is grounded via the substrate 300. The protection ring is fixed on the third surface 330 of the substrate 300.

The protection ring is located around the sensing chip 301 and the molding layer 305 and a portion of the protection ring further extends to the above of the molding layer 306 and exposes the surface of the sensing region 311. In another embodiment, the protection ring is only located around the sensing chip 301 and the molding layer 306, and exposes the surface of the molding layer 306.

The protection ring is made of metal such as copper, tungsten, aluminum, silver or gold. The protection ring provides an electrostatic protection to the sensing chip 301. The protection ring is electrically conductive since it is made of metal. Static electricity is prone to be generated when the user's finger contact the sensing region 311. Electrostatic charges may be firstly transmitted from the protection ring to the substrate 300, so as to prevent the passivation layer from being broken down by overlarge static voltage. Therefore, the sensing chip 301 is protected, the accuracy of the fingerprint detection is improved, noise of a signal outputted from the sensing chip 301 is eliminated and a signal outputted by the sensing chip is more accurate.

In another embodiment, a housing which encloses the molding layer 306, the sensing chip 301 and the protection ring is further formed. The housing exposes the surface of the sensing region 301. The housing may be a housing of a device or a terminal arranged with the fingerprint recognition chip, or a housing of a packaging structure for the fingerprint recognition chip.

In another embodiment, only the housing which encloses the molding layer 306 and the sensing chip 301 may be formed, without forming the protection ring. The housing exposes the surface of the sensing region 311.

In summary, in the embodiment, after the sensing chip is coupled to the surface of the substrate, the molding layer which exposes the sensing region of the sensing chip is formed on the surface of the substrate and a portion of the surface of the sensing chip. In this case, the molding layer fixes the sensing chip to the substrate, and completely exposes the sensing region while protecting the region other than the sensing region of the sensing chip. Since the surface of the sensing region is not covered, the user's fingerprint information can be directly acquired in the sensing region of the sensing chip, the sensing capability of the sensing chip can be fully utilized. Thus, the sensitivity of the formed packaging structure for the fingerprint recognition chip is improved. In addition, the packaging method for the fingerprint recognition chip is simple, and the fabricating cost is reduced.

Accordingly, a packaging structure for a fingerprint recognition chip formed with the above method is further provided according to an embodiment of the present disclosure. Referring to FIG. 8, The packaging structure includes:

a substrate 300;
a sensing chip 301 coupled to the substrate 300, where the sensing chip 301 includes a first surface 310 and a second surface 320 facing away from the first surface 310, the sensing chip 301 further includes a sensing region 311 located on the first surface 310 and the second surface 320 of the sensing chip 301 faces to the substrate 300; and
a molding layer 306 located on the substrate and a portion of the surface of the sensing chip 301, where the molding layer 306 exposes the sensing region 301.

The above structure is further described in detail hereinafter.

The substrate 300 is a rigid substrate or a flexible substrate. In the present embodiment, the substrate 300 is a rigid substrate such as a PCB substrate, a glass substrate, a metal substrate, a semiconductor substrate or a polymer substrate.

In the embodiment, the substrate 300 includes a third surface 330 which is to be coupled to a sensing chip subsequently. The third surface 330 of the substrate 300 includes a wiring layer (not shown) and a second pad 331. The wiring layer is connected to the second pad 331, and the second pad 331 is electrically connected to a chip circuit on a surface of the sensing chip.

In an embodiment, a connection portion is formed at one end of the substrate 300, for electrically connecting the sensing chip with an external circuit. The connection portion may be made of conductive material, and is electrically connected to the wiring layer. In this case, the chip circuit on the sensing chip may be electrically connected to an external circuit or external device via the wiring layer and the connection portion on the third surface 330 of the substrate 300, to transfer an electrical signal.

In the embodiment, the sensing chip 301 is fixed to the first surface 330 of the substrate 300 with a first adhesive layer.

In the present embodiment, in the sensing region 311 of the sensing chip 301, a sensing device for acquiring user's fingerprint information is arranged. The sensing device includes a capacitive structure or an inductive structure, with which the user's fingerprint information can be detected and received in the sensing region 311.

The first surface 310 further includes a peripheral region 312 which is located on the first surface 310 and encloses the sensing region 311. A chip circuit is further arranged in the sensing region 311 and peripheral region 312 of the sensing chip 301 and is electrically connected to the sensing device in the sensing region 311, for processing an electrical signal outputted by the sensing device. In the embodiment, at least one capacitive plate is arranged in the sensing region 311.

The sensing chip 301 further includes a first pad 313 located on a surface of the peripheral region 312 of the sensing chip. The chip circuit is electrically connected to the first pad 313. In the embodiment, the surface of the sensing region 311 of the sensing chip 301 further includes a passivation layer which is made of insulation material.

The packaging structure further includes a conductive wire 302, and two ends of the conductive wire 302 are respectively connected to the first pad 313 and the second pad 331. In this case, the sensing chip 301 is electrically connected to the substrate 300. The conductive wire 302 is made of metal such as copper, tungsten, aluminum, gold or silver.

A point on the conductive wire 302 having a maximum distance to the surface of the substrate 300 is determined as a vertex, which is higher than the first surface 310 of the sensing chip 301. Since the conductive wire 302 is wrapped by a molding layer 306, the vertex should be lower than the surface of the molding layer 306, such that the molding layer can completely wrap the conductive wire 302, thereby avoiding the conductive wire 302 from being exposed. In the embodiment, a distance between the surface of the molding layer 306 and the surface of the peripheral region 312 of the sensing chip 301 ranges from 100 microns to 150 microns.

In the embodiment, the molding layer 306 covers the surface of the peripheral region 312 while exposing the surface of the sensing region 311. In this way, the user's finger can directly contact the sensing region 311, thereby improving the sensitivity of the sensing chip. In other embodiments, the surface of the sensing region 311 may be covered by the molding layer which is thinner than the molding layer covering the surface of the peripheral region 312.

The molding layer 306 is made for protecting the peripheral region 312 of the sensing region 301, the conductive wire 302 and the substrate 300, and for fixing the sensing chip 301 to the surface of the substrate 300. In addition, the molding layer 306 further wraps the conductive wire 302, thereby electrically isolating the conductive wire 302 from the sensing chip 301 or the external environment.

The molding layer 306 is made of polymeric material which has good flexibility, ductility and covering capability. The polymer material may be epoxy resin, polyimide resin, benzocyclobutene resin, polybenzoxazole resin, polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate copolymer, polyvinyl alcohol or other appropriate polymeric material.

In an embodiment, a protection ring is further formed on the surface of the substrate 300 and encloses the sensing chip 301 and the molding layer 306. The protection ring is made of metal and is grounded via the substrate 300. The protection ring is fixed on the third surface 330 of the substrate 300. The protection ring is located around the sensing chip 301 and the molding layer 306, and a portion of the protection ring further extends to the above of the molding layer 306 and exposes the surface of the sensing region 311. In another embodiment, the protection ring is only located around the sensing chip 301 and the molding layer 306, and exposes the surface of the molding layer 306. The protection ring is made of metal such as copper, tungsten, aluminum, silver or gold.

In another embodiment, a housing which encloses the molding layer 306, the sensing chip 301 and the protection ring is further formed. The housing exposes the surface of the sensing region 301. The housing may be a housing of a device or a terminal arranged with a fingerprint recognition chip, or a housing of a packaging structure for the fingerprint recognition chip.

In another embodiment, only the housing which encloses the molding layer 306 and the sensing chip 301 may be formed, without forming the protection ring. The housing exposes the surface of the sensing region 311.

Compared with the conventional technologies, the technical solutions according to the present disclosure have following advantages.

In the method according to the present disclosure, after the sensing chip is coupled to the surface of the substrate, the molding layer which exposes the sensing region of the sensing chip is formed on the surface of the substrate and a portion of the surface of the sensing chip. In this case, the molding layer fixes the sensing chip to the substrate, and completely exposes the sensing region while protecting the region other than the sensing region of the sensing chip. Since the surface of the sensing region is not covered, the user's fingerprint information can be directly acquired in the sensing region of the sensing chip, and thus the sensing capability of the sensing chip can be fully utilized. Thus, the sensitivity of the formed packaging structure for the fingerprint recognition chip is improved. In addition, the packaging method for the fingerprint recognition chip is simple, and the fabricating cost is reduced.

Further, the molding layer is formed by an injection molding process in which a specially prepared mold is adopted to form the molding layer exposing the sensing region. The mold includes the fourth surface including a sensing-corresponding region and a peripheral-corresponding region. A surface of the sensing-corresponding region is higher than the surface of the peripheral-corresponding region. Therefore, in a case that the fourth surface of the mold is pressed towards the substrate and the sensing chip, the surface of the sensing-corresponding region of the mold can contact the surface of the sensing region of the sensing chip, while a molding space is formed between a surface of a region other than the sensing region of the sensing chip and the fourth surface of the mold. In this case, after mold compound is injected into the molding space and is then cured, a formed molding layer can cover the region other than the sensing region of the sensing chip and expose the sensing region.

Furthermore, a passivation layer is provided on the surface of the sensing region of the sensing chip. The passivation layer is made of insulation material. Since the molding layer exposes the sensing region of the sensing chip, the user's finger can directly contact the surface of the sensing region. The user's finger can be electrically isolated from a chip circuit or sensing device in the sensing region by the passivation layer arranged on the surface of the sensing region of the sensing chip, thereby isolating and protecting the chip circuit or sensing device in the sensing region. Therefore, although the molding layer exposes the sensing region of the sensing chip, the working performance of sensing chip is not affected.

In the structure according to the present disclosure, the sensing chip is coupled to the surface of the substrate, and the molding layer which exposes the sensing region of the sensing chip is provided on the surface of the substrate and a portion of the surface the sensing chip. The molding layer fixes the sensing chip and the substrate to each other, and completely exposes the sensing region while protecting the region other than the sensing region of the sensing chip. Since the surface of the sensing region is not covered, the user's fingerprint information can be directly obtained by the sensing chip, thereby fully utilizing the sensing capability of the sensing chip. Thus, the sensitivity of the packaging structure for the fingerprint recognition chip is improved, and the fabricating cost of the fingerprint recognition chip is reduced.

In summary, in the embodiments, the sensing chip is coupled to the surface of the substrate, and the molding layer which exposes the sensing region of the sensing chip is provided on the surface of the substrate and a portion of the surface the sensing chip. The molding layer fixes the sensing chip and the substrate to each other, and completely exposes the sensing region while protecting the region other than the sensing region of the sensing chip. Since the surface of the sensing region is not covered, the user's fingerprint information can be directly obtained by the sensing chip, thereby fully utilizing the sensing capability of the sensing chip. Thus, the sensitivity of the packaging structure for the fingerprint recognition chip is improved, and the fabricating cost of the fingerprint recognition chip is reduced.

Although the technical solution is disclosed above, it is not limited thereto. Various alternations and modifications can be made to the technical solution of the present disclosure by those skilled in the art without deviation from the spirit and scope of the present disclosure. Therefore, the scope of protection of the present disclosure is in conformity with the scope defined by the appended claims.

1. A chip packaging structure, comprising:
a substrate;
a sensing chip coupled to the substrate, wherein the sensing chip comprises a first surface and a second surface facing away from the first surface, the sensing chip further comprises a sensing region located in the first surface, and the second surface of the sensing chip faces to the substrate; and
a molding layer located on the substrate and a portion of the first surface of the sensing chip, wherein the molding layer exposes the sensing region.

2. The chip packaging structure according to claim 1, wherein the sensing chip further comprises a peripheral region which is located in the first surface and encloses the sensing region, and the peripheral region is covered by the molding layer.

3. The chip packaging structure according to claim 2, further comprising:
a chip circuit arranged in the sensing region of the sensing chip and the peripheral region of the sensing chip; and
a first pad located on a surface of the peripheral region of the sensing chip,
wherein the chip circuit is electrically connected to the first pad, the substrate further comprises a third surface to which the sensing chip is coupled, and a second pad is arranged on the third surface of the substrate, and is electrically connected to the first pad.

4. The chip packaging structure according to claim 3, further comprising a conductive wire, wherein two ends of the conductive wire are electrically connected to the first pad and the second pad respectively.

5. The chip packaging structure according to claim 4, wherein the molding layer wraps the conductive wire.

6. The chip packaging structure according to claim 1, wherein a distance between a surface of the molding layer and the first surface of the sensing chip ranges from 100 microns to 150 microns, and the molding layer is made of polymer material.

7. The chip packaging structure according to claim 1, further comprising a passivation layer located on a surface of the sensing region of the sensing chip.

8. The chip packaging structure according to claim 7, wherein the passivation layer is made of insulation material.

9. A chip packaging method, comprising:
providing a substrate;
coupling a sensing chip to the substrate, wherein the sensing chip comprises a first surface and a second surface facing away from the first surface, the sensing chip further comprises a sensing region located in the first surface, and the second surface of the sensing chip faces to the substrate; and
forming a molding layer on the substrate and a portion of the first surface of the sensing chip, wherein the molding layer exposes the sensing region.

10. The chip packaging method according to claim 9, wherein the sensing chip further comprises a peripheral region which is located in the first surface and encloses the sensing region, and the peripheral region is covered by the molding layer.

11. The chip packaging method according to claim 10, wherein the molding layer is formed by an injection molding process.

12. The chip packaging method according to claim 11, wherein the injection molding process comprises:
providing a mold, wherein the mold comprises a fourth surface and has a sensing-corresponding region and a peripheral-corresponding region, the fourth surface comprises a surface of the peripheral-corresponding region and a surface of the sensing-corresponding region that is higher than the surface of the peripheral-corresponding region;
pressing the fourth surface of the mold towards the substrate and the sensing chip to form a molding space, wherein the sensing-corresponding region of the mold corresponds to the sensing region of the sensing chip; and
filling a mold compound into the molding space and curing the mold compound to form the molding layer.

13. The chip packaging method according to claim 10, wherein
a chip circuit is arranged in the sensing region of the sensing chip and peripheral region of the sensing chip,
a first pad is arranged on a surface of the peripheral region of the sensing chip and is electrically connected to the chip circuit,
the substrate further comprises a third surface to which the sensing chip is coupled, and a second pad is arranged on the third surface of the substrate, and
the method further comprises: forming a conductive structure between the first pad and the second pad to electrically connect the first pad to the second pad.

14. The chip packaging method according to claim 13, further comprising:
forming a conductive wire before forming the molding layer, wherein two ends of the conductive wire are respectively connected to the first pad and the second pad.

15. The chip packaging method according to claim 14, wherein the molding layer wraps the conductive wire.

16. The chip packaging method according to claim 9, wherein
a distance between a surface of the molding layer and the first surface of the sensing chip ranges from 100 microns to 150 microns, and
the molding layer is made of polymer material.

17. The chip packaging method according to claim 9, further comprising:
forming a passivation layer on a surface of the sensing region of the sensing chip.
